(19) United States
(12) Patent Application Publication
(10) Pub. No.: US 2012/0273787 A1
(43) Pub. Date: Nov. 1, 2012

(54) THIN FILM TRANSISTOR AND MANUFACTURING METHOD THEREOF

(76) Inventors: Hwa Yeul OH, Asan-si (KR); O Sung Seo, Seoul (KR); Je Hyeong Park, Hwaseong-si (KR); Shin II Choi, Hwaseong-si (KR); Dong-Won Woo, Asan-si (KR); Ji-Young Park, Hwaseong-si (KR); Jean Ho Song, Yongin-si (KR); Sang Gab Kim, Seoul (KR)

(21) Appl. No.: 13/244,086

(22) Filed: Sep. 23, 2011

(30) Foreign Application Priority Data
Apr. 29, 2011 (KR) 10-2011-0040718

(51) Int. Cl. H01L 33/08; H01L 21/336

(52) U.S. Cl. 257/59; 438/158; 257/72; 257/E33.053; 257/E21.412

(57) ABSTRACT

In a thin film transistor array panel according to an exemplary embodiment of the present invention, a plasma process using a mixed gas including hydrogen gas and nitrogen gas with a ratio of a predetermined value is undertaken before depositing a passivation layer. In this manner, performance deterioration of the thin film transistor may be prevented and simultaneously, haze in a transparent electrode may be prevented. Alternatively, a first passivation layer is depsoited, then removed. A passivation layer is again re-deposited, such that little or no haze is present in the resulting passivation layer.

### CROSS-REFERENCE TO RELATED APPLICATION

This application claims priority to, and the benefit of, Korean Patent Application No. 10-2011-0040718 filed in the Korean Intellectual Property Office on Apr. 29, 2011, the entire contents of which are incorporated herein by reference.

### BACKGROUND

(a) Field of the Disclosure

Embodiments of the present invention relate generally to flat panel displays. Embodiments of the present invention relate more specifically to a thin film transistor array panel and a manufacturing method thereof.

(b) Description of the Related Art

Liquid crystal displays (LCDs) are one of the most widely used flat panel displays, and they display images by applying voltages to field-generating electrodes to generate an electric field in an LC layer. This electric field determines orientations of LC molecules therein, which in turn adjusts the polarization of incident light.

Benefits of the liquid crystal display has include what is typically their light weight and thin form factor. However, liquid crystal displays also typically suffer from the drawbacks of side visibility being lower than front visibility. Liquid crystal arrangements and driving methods of various types have been developed to solve this drawback. One configuration employed to realize a wider viewing angle, the field generating electrodes are formed on one substrate rather than two.

In this configuration, a passivation layer is deposited directly on the transparent electrode. However, when depositing the passivation layer directly on the transparent electrode, a haze phenomenon can occur, where the passivation layer is rendered opaque by a reduction reaction with the transparent electrode.

The above information disclosed in this Background section is only for enhancement of understanding of the background of the invention and therefore it may contain information that does not form the prior art.

### SUMMARY

Accordingly, the present invention provides a thin film transistor array panel that prevents a haze phenomenon from occurring in a passivation layer, as well as a manufacturing method thereof.

A manufacturing method of a thin film transistor array panel according to an exemplary embodiment of the present invention includes: forming a gate conductor on a substrate; forming a gate insulating layer on the gate conductor; forming a semiconductor, a source electrode, and a drain electrode on the gate insulating layer; forming a transparent electrode on the gate insulating layer and a portion of the drain electrode; executing a plasma process during which a mixed gas is directed upon the semiconductor, the source electrode, the drain electrode, the mixed gas including hydrogen gas and nitrogen gas; and after the executing, forming a passivation layer on the semiconductor, the source electrode, the drain electrode, and the transparent electrode.

A ratio of hydrogen gas to nitrogen gas in the mixed gas may be about 1:10 to about 1:50.

A ratio of hydrogen gas to nitrogen gas in the mixed gas may be about 1:10 to about 1:30.

The source electrode and the drain electrode may include copper.

The source electrode and the drain electrode may include titanium.

The plasma process may be executed with a pressure of about 500 mT to about 2500 mT.

The plasma process may be executed with a power source of 0.1 W/mm² to about 5 W/mm².

The plasma process may be executed for about 5 seconds to about 50 seconds.

A manufacturing method of a thin film transistor array panel according to another embodiment of the present invention includes: forming a gate conductor on a substrate; forming a gate insulating layer on the gate conductor; forming a semiconductor, a source electrode, and a drain electrode on the gate insulating layer; forming a transparent electrode on the gate insulating layer and a portion of the drain electrode; depositing a first passivation layer on the semiconductor, the source electrode, the drain electrode, and the transparent electrode; removing the first passivation layer ; and after the removing, depositing a second passivation layer on the semiconductor, the source electrode, the drain electrode, and the transparent electrode.

A thin film transistor array panel according to a further exemplary embodiment of the present invention includes: a gate conductor disposed on a substrate; a gate insulating layer disposed on the gate conductor; a semiconductor disposed on the gate insulating layer; a source electrode and a drain electrode disposed on the semiconductor and the gate insulating layer; a transparent electrode disposed on the gate insulating layer and a portion of the drain electrode and directly contacting the drain electrode; and a passivation layer disposed on the source electrode, the drain electrode, and the transparent electrode, wherein the source electrode, the drain electrode, and the transparent electrode are plasma-processed with a mixed gas including hydrogen gas and nitrogen gas.

The source electrode and the drain electrode may include copper.

The source electrode and the drain electrode may include titanium.

In a thin film transistor array panel according to an exemplary embodiment of the present invention, a plasma process using a mixed gas including hydrogen gas and nitrogen gas with a ratio of a predetermined value is undertaken before depositing a passivation layer. In this manner, performance deterioration of the thin film transistor may be prevented and additionally, haze in a transparent electrode may be prevented. These advantages can also be accomplished by depositing a material layer forming the passivation layer, removing the material layer, and then re-depositing the passivation layer.

### BRIEF DESCRIPTION OF THE DRAWINGS

FIG. 1 is a layout view of a thin film transistor array panel according to an exemplary embodiment of the present invention.

FIG. 2 is a cross-sectional view of the thin film transistor array panel of FIG. 1 taken along line II-II.

FIG. 3, FIG. 5, FIG. 7, and FIG. 9 are layout views sequentially showing a manufacturing method of a thin film transistor array panel according to an exemplary embodiment of the present invention.

FIG. 4 is a cross-sectional view of the thin film transistor array panel of FIG. 3 taken along line IV-IV.

FIG. 6 is a cross-sectional view of the thin film transistor array panel of FIG. 5 taken along line VI-VI.

FIG. 8 is a cross-sectional view of the thin film transistor array panel of FIG. 7 taken along line VIII-VIII.

FIG. 10 is a cross-sectional view of the thin film transistor array panel of FIG. 9 taken along line X-X.

FIG. 11A and FIG. 11B are cross-sectional view sequentially showing a portion of a manufacturing method of a thin film transistor array panel according to an exemplary embodiment of the present invention.

FIG. 12A to FIG. 12C are cross-sectional view sequentially showing a portion of a manufacturing method of a thin film transistor array panel according to another exemplary embodiment of the present invention.

### DETAILED DESCRIPTION OF EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereafter, a thin film transistor array panel according to an exemplary embodiment of the present invention will be described with reference to accompanying drawings.

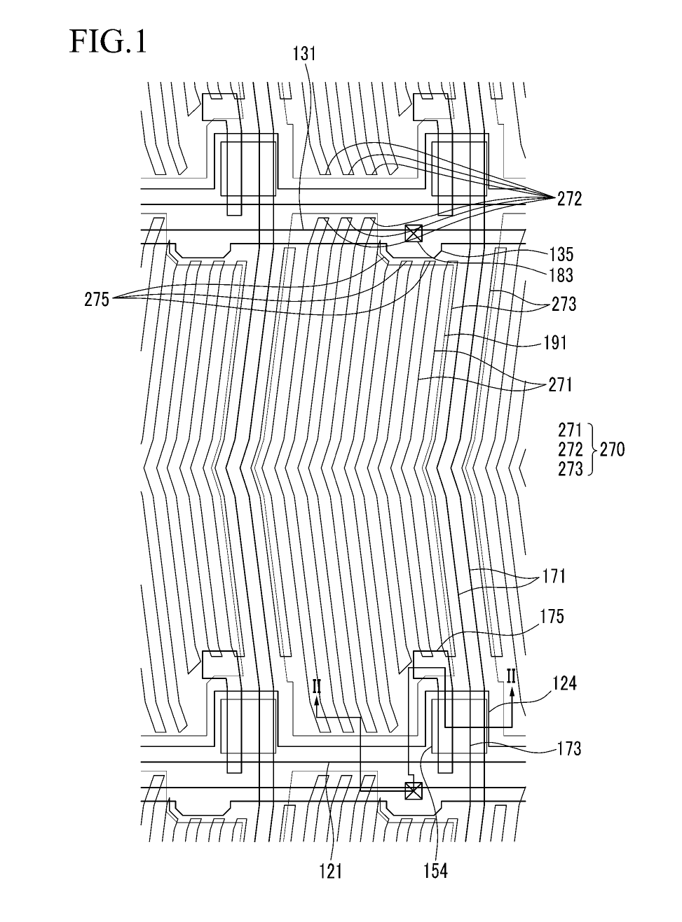

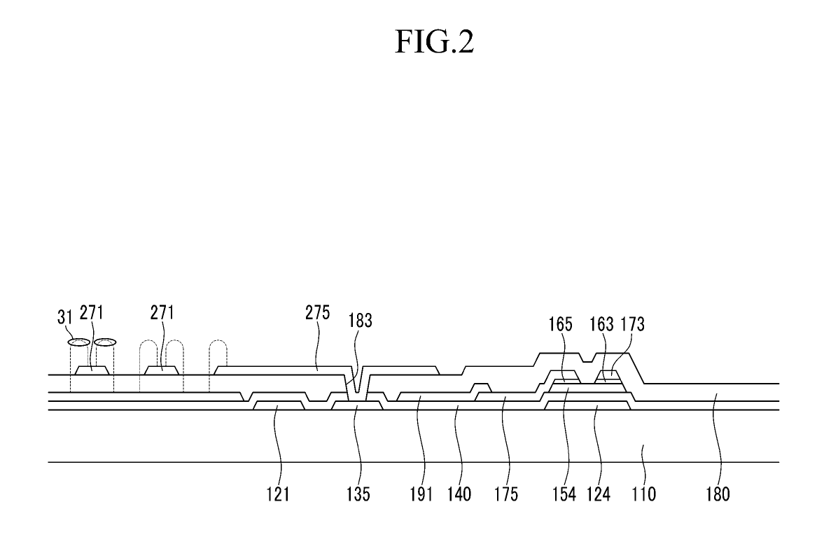

FIG. 1 is a layout view of a thin film transistor array panel according to an exemplary embodiment of the present invention, and FIG. 2 is a cross-sectional view of the thin film transistor array panel of FIG. 1 taken along line II-II.

Referring to FIG. 1 and FIG. 2, in a thin film transistor array panel according to an exemplary embodiment of the present invention, a gate conductor including a gate line 121 and a reference voltage line 131 is formed on an insulation substrate 110 made of a transparent glass or plastic. The gate line 121 includes a gate electrode 124 and an end portion (not shown) having a wide area for connection to other layers or to an external driving circuit. The gate line 121 may be made of a material such as an aluminum-based metal comprising aluminum (Al) or aluminum alloys, a silver-based metal containing silver (Ag) or silver alloys, a copper-based metal such as copper (Cu) or copper alloys, a molybdenum-based metal like molybdenum (Mo) or molybdenum alloys, chromium (Cr), tantalum (Ta), and/or titanium (Ti). The gate line 121 may also have a multilayer structure including at least two conductive layers with different physical properties.

The reference voltage line 131 transmits a predetermined reference voltage, and includes an expansion 135 for connection to a reference electrode 270 that will be further described below. The reference voltage line 131 is connected to the reference electrode 270, thereby transmitting the reference voltage to the reference electrode 270. The reference voltage line 131 may be generally parallel to the gate line 121 and may be made of the same material as the gate line 121.

A gate insulating layer 140 made of silicon nitride (SiNx) or silicon oxide (SiOx) is formed on the gate conductors 121 and 131. The gate insulating layer 140 may have a multilayer structure including at least two conductive layers having different physical properties.

A semiconductor island 154 made of amorphous silicon or polysilicon is formed on the gate insulating layer 140. The semiconductor island 154 overlaps at least a portion of the gate electrode 124.

Ohmic contacts 163 and 165 are formed on the semiconductor island 154. The ohmic contacts 163 and 165 may be made of a material such as n+ hydrogenated amorphous silicon, in which an n-type impurity such as phosphorus is doped at a high concentration, or silicide. The ohmic contacts 163 and 165 may be disposed in a pair, on the semiconductor island 154.

A data conductor that includes a data line 171, a source electrode 173 and a drain electrode 175 is formed on the ohmic contacts 163 and 165 and on the gate insulating layer 140.

The data line 171 has an end portion (not shown) having a wide area for connection to other layers or to an external driving circuit. The data line 171 transmits a data signal and mainly extends in a longitudinal direction, thereby intersecting the gate line 121 and the reference voltage line 131. The data line 171 forms a pixel area along with the gate line 121. Here, the data line 171 may have first and second curved portions each having a curved shape to obtain greater transmittance, where the curved portions meet in the middle region of the pixel area to form a general “V” shape. The curved portions may have a predetermined angle with respect to each other.

The first curved portion of the data line 171 may form an angle of about 7° along a rubbing direction of an alignment layer that will be described later. The second curved portion, disposed in the middle region of the pixel area, may form an angle of about 7° to about 15° with the first curved portion.

The source electrode 173 is a portion of the data line 171, and is collinearly disposed with the data line 171. The drain electrode 175 is formed to be generally parallel to the source electrode 173. Accordingly, the drain electrode 175 is also generally parallel to the data line 171.

The gate electrode 124, the source electrode 173, and the drain electrode 175 collectively form a thin film transistor (TFT) along with the semiconductor island 154, and the channel of the thin film transistor is formed in the semiconductor 154 between the source electrode 173 and the drain electrode 175.

A liquid crystal display according to an exemplary embodiment of the present invention includes the source electrode 173 collinearly disposed with the data line 171 and the drain electrode 175 extending parallel to the data line 171, such that the width of the thin film transistor may be widened without increasing the area of the data conductor, thereby increasing the aperture ratio of the liquid crystal display.

The data line 171 and the drain electrode 175 may include a refractory metal such as molybdenum, chromium, tantalum, and titanium, and a conductor having low resistivity such as copper. For example, the data line 171 and the drain electrode 175 may include titanium and copper.

A pixel electrode 191 is formed on a portion of the drain electrode 175 and the gate insulating layer 140.

The pixel electrode 191 includes a pair of curved edges substantially parallel to the first curved portion and the second curved portion of the data line 171.

The pixel electrode 191 covers a portion of the drain electrode 175 and is disposed thereon such that it is electrically and physically connected to the drain electrode 175.

The pixel electrode 191 may be made of a transparent conductive material such as polycrystalline, single crystalline, or amorphous indium tin oxide (ITO) or indium zinc oxide (IZO).

A passivation layer 180 is formed on the data conductor 171 and 175, the exposed semiconductor 154, and the pixel electrode 191. The passivation layer 180 is made of an inorganic insulator such as silicon nitride and silicon oxide. However, the passivation layer 180 may be made of an organic insulator and may have a generally flat surface. The organic insulator can have photosensitivity, and preferably, its dielectric constant is not greater than about 4.0. Also, the passivation layer 180 may have a dual-layered structure of a lower inorganic layer and an upper organic layer so that it may not harm the exposed portion of the semiconductor 154 while still sustaining the desirable insulation characteristics of the organic layer.

Before forming the passivation layer 180 on the data conductors 171 and 175 the exposed semiconductor 154, and the pixel electrode 191, a plasma process using a mixed gas having a ratio of about 1:10 to 1:50 of hydrogen gas and nitrogen gas is executed, or a material for forming the passivation layer 180 is deposited on the entire surface of the substrate, the material layer is removed, and the passivation layer 180 is again formed. This prevents occurrence of a haze phenomenon of the passivation layer 180 that may be generated when forming the passivation layer 180 directly on transparent conductive material such as the pixel electrode 191. This will be described in further detail below.

The passivation layer 180 has a contact hole (not shown) exposing the end portion of the data line 171, and the passivation layer 180. Additionally, the gate insulating layer 140 have a contact hole 183 exposing the expansion 135 of the reference voltage line 131 as well as a contact hole (not shown) exposing the end portion of the gate line 121.

A reference electrode 270 is formed on the passivation layer 180. The reference electrode 270 overlaps the pixel electrode 191 and includes a plurality of branch electrodes 271, a transverse connection 272 connecting a plurality of branch electrodes 271, and a longitudinal connection 273 connecting transverse connections 272. The reference electrode 270 may be made of a transparent conductive material such as polycrystalline, single crystalline or amorphous indium tin oxide (ITO) or indium zinc oxide (IZO).

The transverse connection 272 of the reference electrode 270 has a reference electrode expansion 275 extending toward the expansion 135 of the reference voltage line 131. The reference electrodes 270 that are disposed in neighboring pixels are connected to each other.

The expansion 275 of the reference electrode 270 is electrically and physically connected to the reference voltage line 131 through the contact hole 183 in the passivation layer 180 and the gate insulating layer 140.

Although not shown, an alignment layer is coated on the reference electrode 270 and the passivation layer 180, and the alignment layer may be a horizontal alignment layer that is rubbed in a predetermined direction. The rubbing direction of the alignment layer may form an angle of about 5° to about 10°, and preferably about 7°, with the direction in which the branch electrodes of the reference electrode 270 extend.

The pixel electrode 191 receives data voltages from the drain electrode 175, and the reference electrode 270 receives a reference voltage of a predetermined magnitude from the reference voltage line 131. The reference electrodes 270 are connected, so that the entire display area receives the reference voltage from a reference voltage applier disposed outside the display area. The reference voltage is applied to prevent a voltage drop in the display area, thereby receiving the reference voltage of the same magnitude from the reference voltage line 131.

When a data voltage is applied to the pixel electrode 191 and a reference voltage is applied to the reference electrode 270, an electric field is formed in their vicinity, such that liquid crystal molecules 31 of a liquid crystal layer positioned on the two electrodes 191 and 270 are oriented parallel to the direction of the electric field. Polarization of light that passes through the liquid crystal layer changes depending on the rotation direction of the liquid crystal molecules, thus allowing for formation of an image.

The pixel electrode 191 of the thin film transistor array panel according to an exemplary embodiment of the present invention is disposed between the gate insulating layer 140 and the passivation layer 180, and covers a portion of the drain electrode 175 to be physically and electrically connected thereto. Liquid crystal displays using these thin film transistor array panels thus have an increased aperture ratio as compared to liquid crystal displays using conventional thin film transistor array panels in which the pixel electrode is connected to the drain electrode through a contact hole.

Also, the liquid crystal display according to an exemplary embodiment of the present invention includes a source electrode 173 collinearly disposed with the data line 171 and a drain electrode 175 extending parallel to the data line 171, such that the width of the thin film transistor may be widened without increasing the area of the data conductor, thereby further increasing the aperture ratio of the liquid crystal display.

Also, before forming the passivation layer 180 on the data conductor 171 and 175, the exposed semiconductor 154, and the pixel electrode 191, a plasma process using a mixed gas having a ratio of about 1:10 to 1:50 of hydrogen gas and nitrogen gas is performed. Alternatively, a material layer forming the passivation layer 180 is deposited on the whole surface of the substrate, the material layer is removed, and the passivation layer 180 is again formed. This reduces or prevents haze in the passivation layer 180 that can occur when forming the passivation layer 180 directly on transparent conductive materials such as the pixel electrode 191.

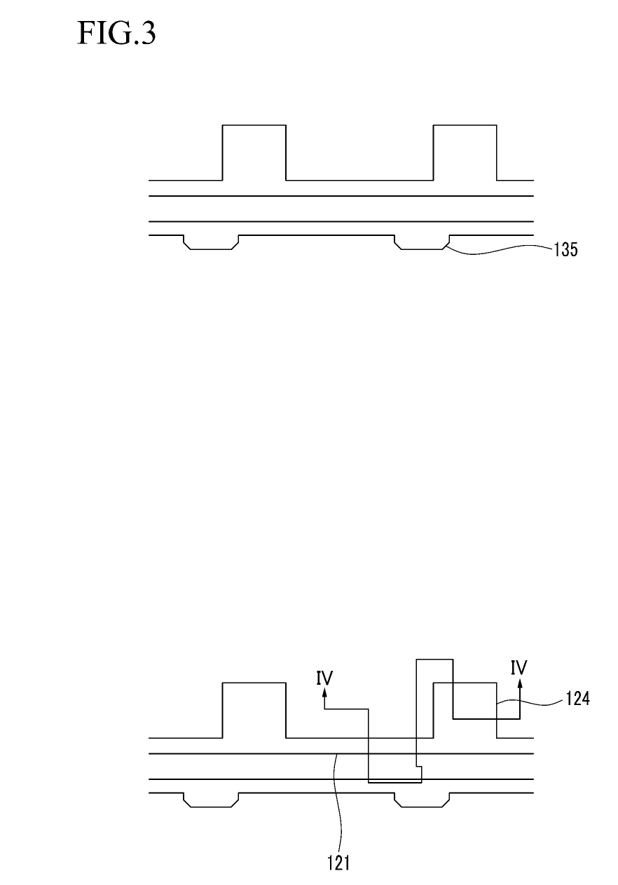

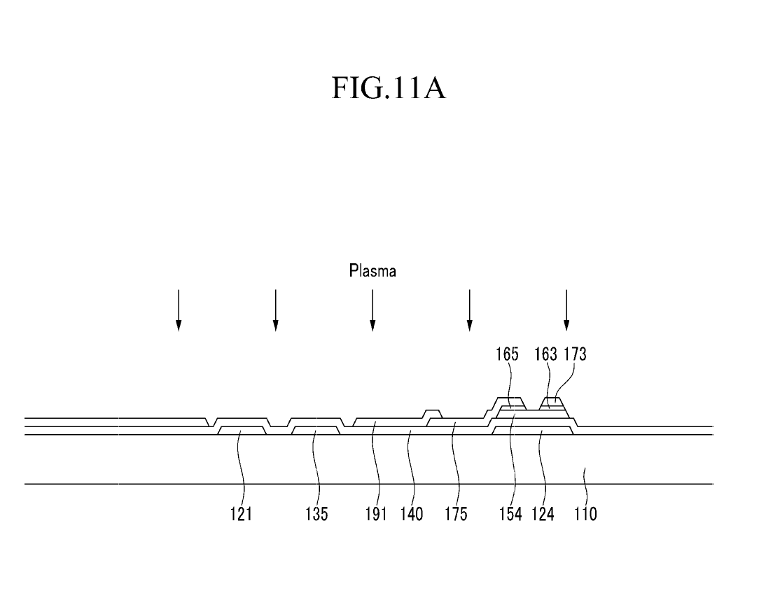

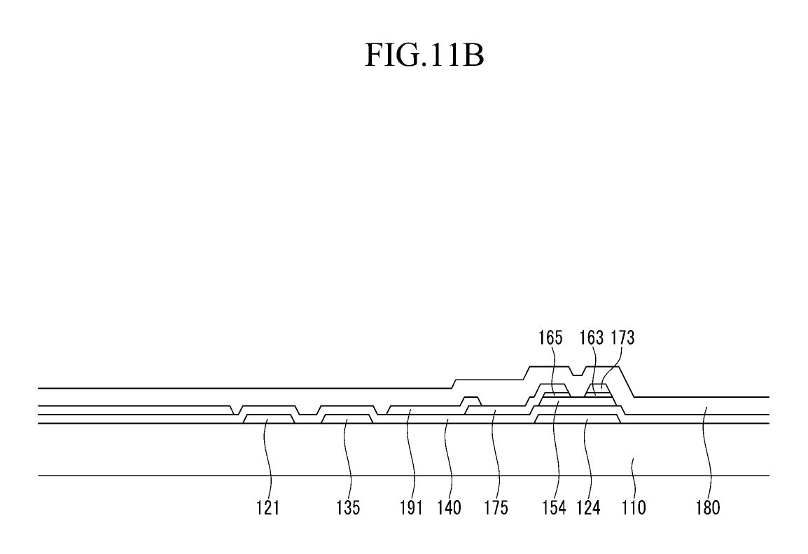

Next, a manufacturing method of a thin film transistor array panel according to an exemplary embodiment of the present invention will be described with reference to FIG. 3 to FIG. 10, FIG. 11A, and FIG. 11B as well as FIG. 1 and FIG. 2.

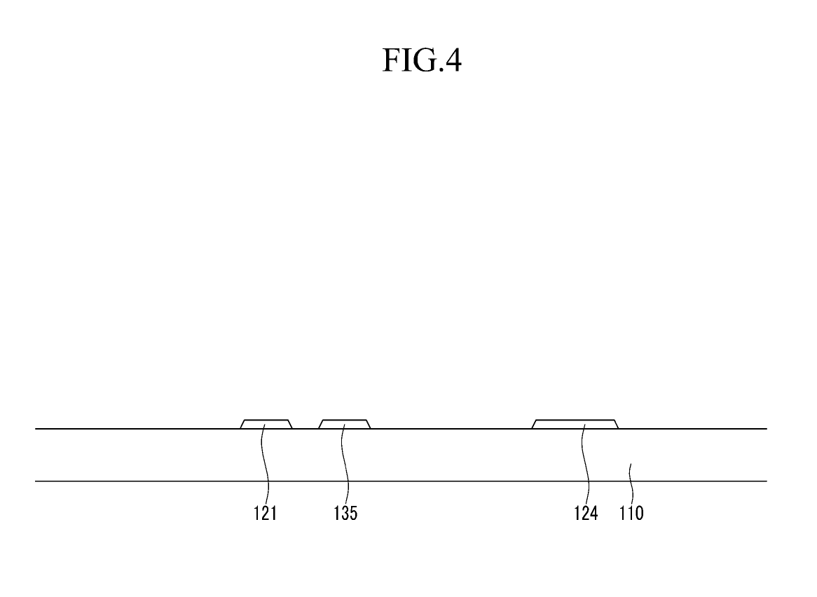

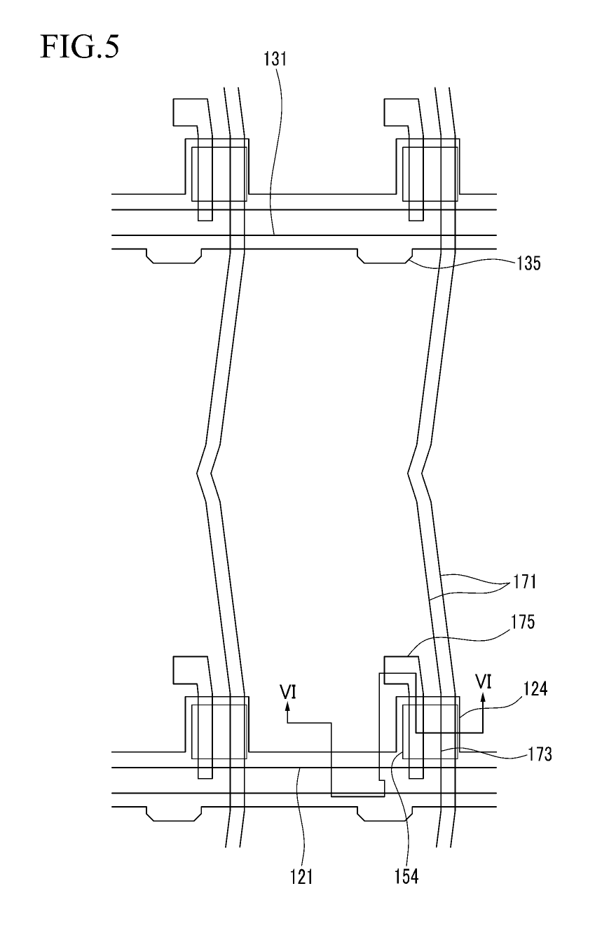

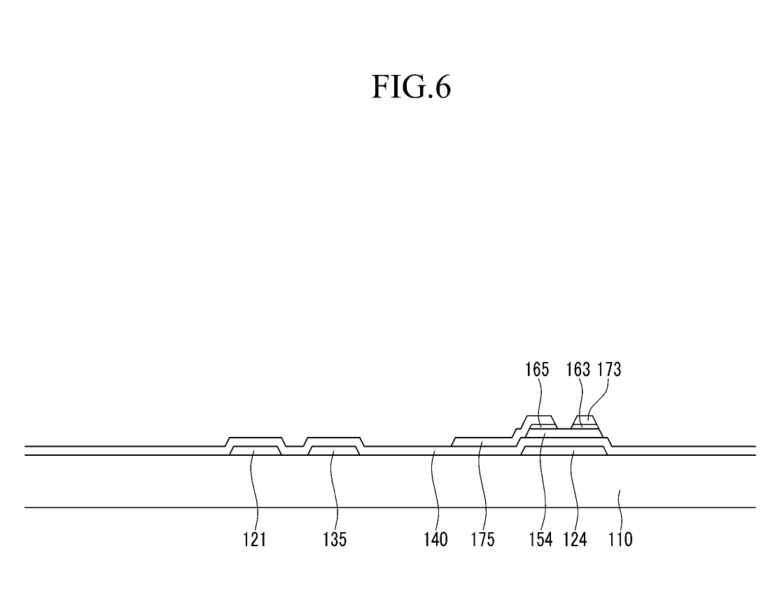

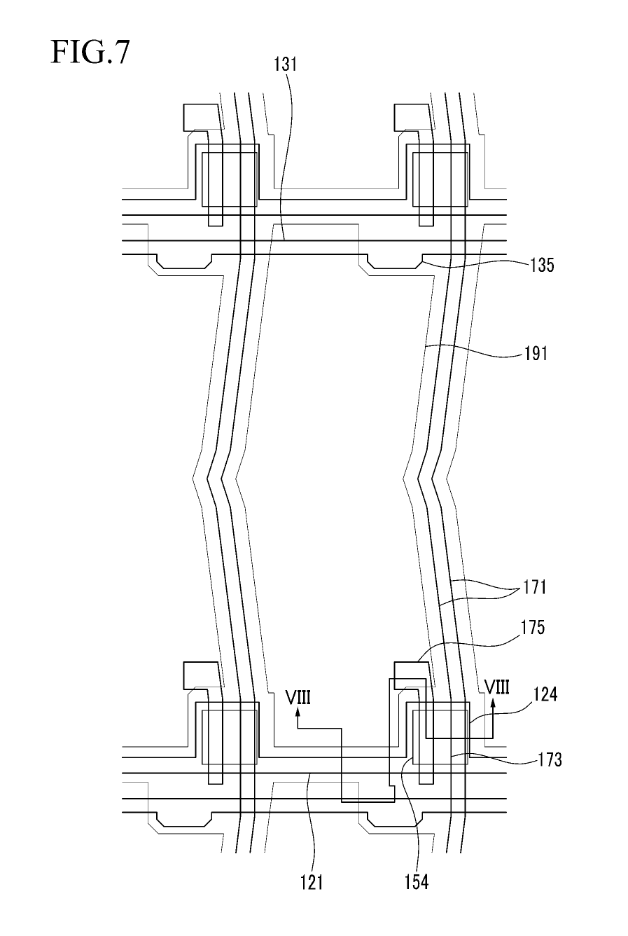

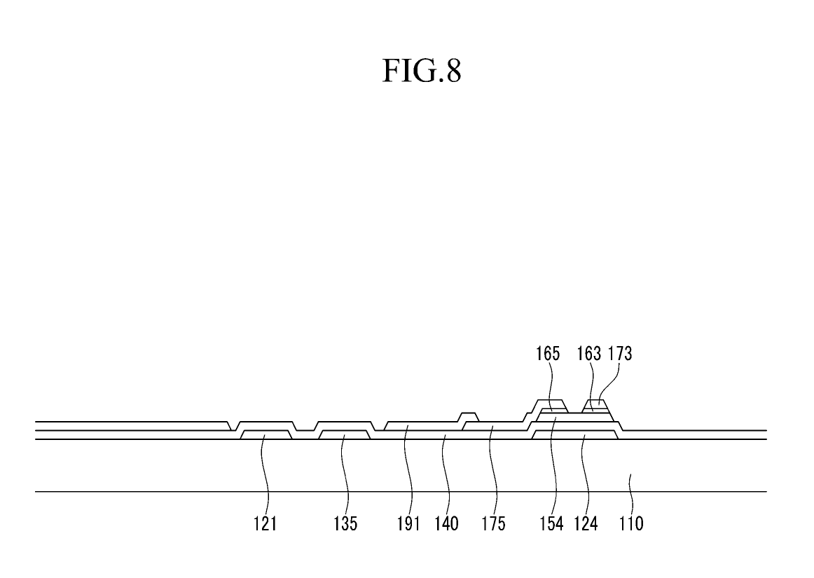

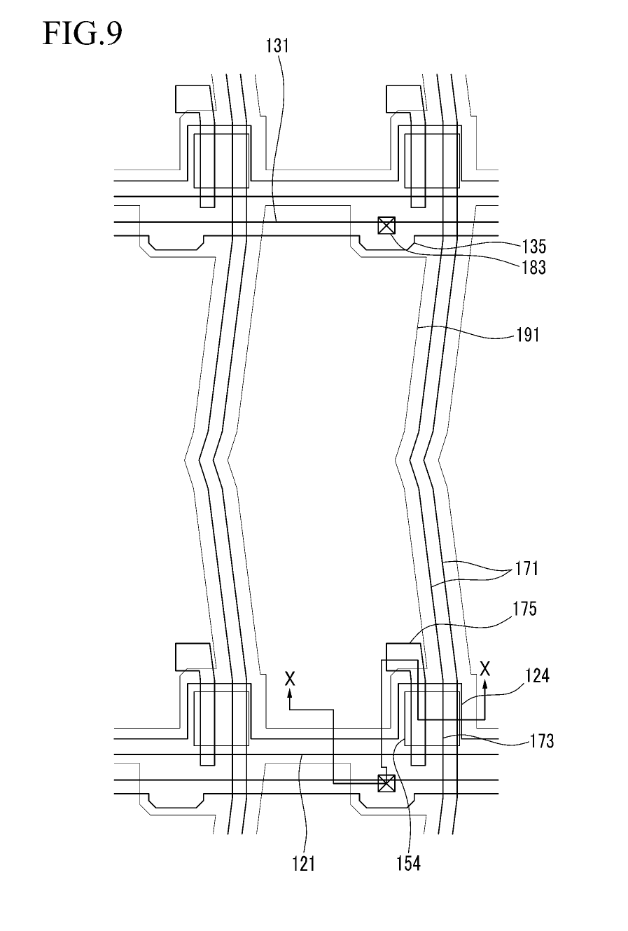

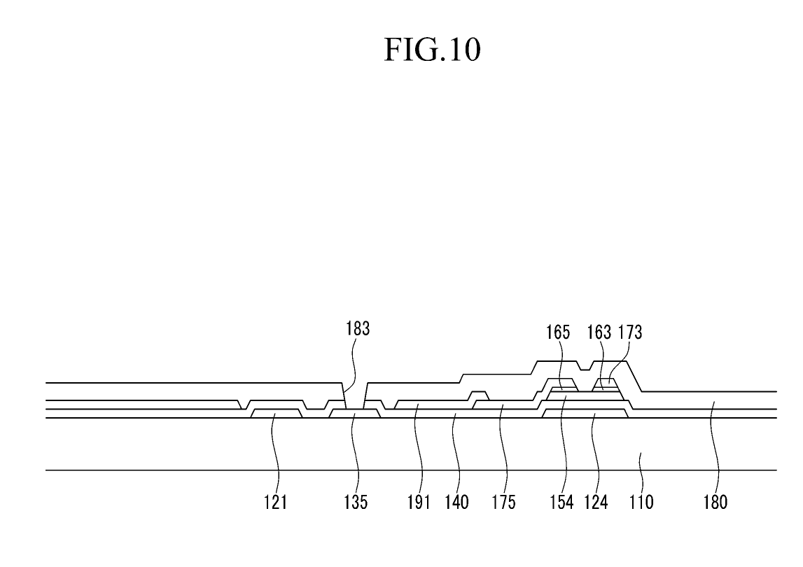

FIG. 3, FIG. 5, FIG. 7, and FIG. 9 are layout views sequentially showing a manufacturing method of a thin film transistor array panel according to an exemplary embodiment of the present invention, FIG. 4 is a cross-sectional view of the thin film transistor array panel of FIG. 3 taken along line IV-IV, FIG. 6 is a cross-sectional view of the thin film transistor array panel of FIG. 5 taken along line VI-VI, FIG. 8 is a cross-sectional view of the thin film transistor array panel of FIG. 7 taken along line VIII-VIII, FIG. 10 is a cross-sectional view of the thin film transistor array panel of FIG. 9 taken along line X-X, and FIG. 11A and FIG. 11B are cross-sectional views sequentially showing part of a manufacturing method of a thin film transistor array panel according to an exemplary embodiment of the present invention.

Firstly, referring to FIG. 3 and FIG. 4, a gate line 121, including a gate electrode 124 and a reference voltage line 131, is formed on the insulation substrate 110. These lines 121, 124 and 131 are collectively a gate conductor.

The gate conductor may be formed by depositing a metal such as an aluminum-based metal like aluminum (Al) or aluminum alloys, a silver-based metal such as silver (Ag) or silver alloys, a copper-based metal such as copper (Cu) or copper alloys, a molybdenum-based metal like molybdenum (Mo) or molybdenum alloys, chromium (Cr), tantalum (Ta), or titanium (Ti). The deposited metal is then patterned through a photolithography process.

Next, referring to FIG. 5 and FIG. 6, a gate insulating layer 140 is deposited on the gate conductor, and a semiconductor island 154, ohmic contacts 163 and 165, and a data conductor are formed on the gate insulating layer 140. The data conductor includes a data line 171 having a source electrode 173 and a drain electrode 175. The data line 171 may have first and second curved portions having curved shapes to obtain the maximum transmittance of the liquid crystal display, and the curved portions may meet at the middle region of the pixel area, thereby forming a “V” shape. The source electrode 173 is generally collinearly disposed with the data line 171, and the drain electrode 175 may be extended generally parallel to the data line 171. By this configuration, the width of the thin film transistor may be widened without increasing the area occupied by the data conductor, and thereby the aperture ratio of the liquid crystal display may be increased. The data line 171 and the drain electrode 175 may include a refractory metal such as molybdenum, chromium, tantalum, or titanium, as well as a conductor having low resistivity such as copper. For instance, the data line 171 and the drain electrode 175 may include titanium and copper.

Referring to FIG. 7 and FIG. 8, a pixel electrode 191 is formed on a portion of the drain electrode 175 and the gate insulating layer 140. The pixel electrode 191 may be formed by depositing a transparent conductive material such as polycrystalline, single crystalline, or amorphous indium tin oxide (ITO) or indium zinc oxide (IZO) and patterning it through photolithography. The pixel electrode 191 is formed directly on, and thus directly contacts, the drain electrode 175, and includes a refractory metal such as titanium or copper.

Next, referring to FIG. 9 and FIG. 10, a passivation layer 180 is formed on the data line 171, the drain electrode 175, the pixel electrode 191, and the exposed semiconductor island 154. The passivation layer 180 may include an inorganic insulator such as silicon nitride or silicon oxide.

Next, as shown in FIG. 1 and FIG. 2, a reference electrode 270 is formed on the passivation layer 180. The reference electrode 270 is made of a transparent conductive material such as polycrystalline, single crystalline, or amorphous indium tin oxide (ITO) or indium zinc oxide (IZO), and is physically and electrically connected to the reference voltage line 131 through the contact hole 183 which is formed in the passivation layer 180 and the gate insulating layer 140.

Next, a method of forming the passivation layer 180 according to an exemplary embodiment of the present invention will be described with reference to FIG. 11A and FIG. 11B.

As shown in FIG. 11A, a plasma process is executed over the entire surface of the substrate 110, including the data line 171, the drain electrode 175, the pixel electrode 191, and the exposed semiconductor island 154. At this time, the plasma process is executed with a mixed gas including hydrogen gas and nitrogen gas in a ratio of about 1:10 to 1:50. The plasma process may use a pressure in the range of about 500 mT to about 2500 mT, the power source may be in the range of 0.1 W/mm² to about 5 W/mm², and the plasma process time may be in the range of about 5 seconds to about 50 seconds.

Next, as shown in FIG. 11B, a passivation layer 180 is formed on the data line 171, the drain electrode 175, the pixel electrode 191, and the exposed semiconductor island 154 that have undergone the plasma process. The passivation layer 180 includes an inorganic insulator such as silicon nitride or silicon oxide. Next, a contact hole (not shown) exposing an end portion of the data line 171 is formed in the passivation layer 180. Also, a contact hole 183 exposing the expansion 135 of the reference voltage line 131 and a contact hole (not shown) exposing an end portion of the gate line 121 are formed in the passivation layer 180 and the gate insulating layer 140.

In this way, before forming the passivation layer 180, the above described plasma process is executed for the whole surface of the substrate 110. Here, nitrogen gas removes ions related to copper and a copper polymer of the remaining data conductor from the exposed semiconductor 154, and hydrogen gas removes a dangling bond of the exposed semiconductor 154. If a plasma process using hydrogen gas is not executed, the performance of the thin film transistor may be deteriorated by the copper component of the remaining data conductor on the semiconductor.

Unfortunately, if a plasma process using hydrogen gas is carried out over a transparent conductive material containing an indium component (such as ITO or IZO), the hydrogen may interact with the indium component to generate the above described haze phenomenon. Fortunately, this phenomenon is reduced or avoided if the plasma process uses hydrogen gas and nitrogen gas in a ratio of about 1:10 to about 1:50, and preferably about 1:10 to about 1:30. In such a process, not only is the haze phenomenon reduced or avoided, but deterioration of the performance of the thin film transistor due to the copper component of the data conductor is also reduced/avoided.

Referring to one experimental example of the present invention, performance of a thin film transistor and transmittance of a transparent electrode and a passivation layer constructed according to an exemplary embodiment of the present invention will now be described.

In the present experimental example, like the thin film transistor array panel according to an exemplary embodiment of the present invention, a thin film transistor has a source electrode and drain electrode made of titanium and copper as well as a transparent electrode directly contacting a portion of the drain electrode, and a passivation layer made of silicon nitride is deposited thereon. Several cases were examined In Case A, a plasma process is not executed before depositing the passivation layer, and in case B, a plasma process is carried out with a mixed gas including hydrogen and nitrogen in a ratio of about 3:1. In case C, a plasma process is carried out with a mixed gas including hydrogen and nitrogen in a ratio of about 1:3, while in case D, a plasma process is carried out with a mixed gas including hydrogen and nitrogen in a ratio of about 1:20. In case E, a plasma process is executed with a mixed gas including hydrogen and nitrogen in a ratio of about 1:30; in case F, a plasma process is carried out with ammonia NH₃ gas, and in case G, a plasma process is carried out using nitrogen gas. For each of these cases, a characteristic value of the thin film transistor and the transmittance of a transparent electrode and a passivation layer are measured. The results thereof are shown in Table 1 below. Referring to the results, if the characteristic value of the thin film transistor is more than about −5 to −5.5, that is, the absolute value is less than 5 to 5.5, it may be regarded as a characteristic of a thin film transistor capable of being used for a display device.

TABLE 1

| | Characteristic value of a thin | |
|---|---|---|
| | film transistor | Transmittance (%) |
| A | −7.37 | 100 |
| B | −4.69 | 43.5 |
| C | −4.39 | 23.9 |
| D | −5.2 | 102 |
| E | −4.505 | 104 |
| F | −6.04 | 99 |
| G | −3.9 | 48 |

Referring to Table 1, in cases D and E, the performance of the resulting thin film transistor is adequate for use in a display device, and the performance of the thin film transistor is excellent compared with the case A in which the plasma process is not executed. Also, compared with the case A in which the plasma process is not executed, it may be confirmed that the transmittance is improved. Case B results in a thin film transistor exhibiting good performance as compared with case A. However, it can be seen that transmittance is greatly deteriorated. In case C, the resulting thin film transistor exhibits good performance as compared with case executed, but similar to case B, the transmittance is greatly deteriorated.

In case F, it may be confirmed that the performance of the thin film transistor also deviates from the range deemed suitable for use in a display device and the transmittance is somewhat deteriorated, and in case G, it may be confirmed that the performance of the thin film transistor is good, however the transmittance is greatly deteriorated.

As described above, like the manufacturing method of the thin film transistor array panel according to an exemplary embodiment of the present invention, a plasma process is executed before forming the passivation layer 180 on the data conductors 171 and 175, the exposed semiconductor 154, and the pixel electrode 191. This plasma process employs a mixed gas including hydrogen and nitrogen in a ratio of about 1:10 to 1:50, which reduces or eliminates the abovementioned haze phenomenon. This process also prevents a compromise in performance of the thin film transistor.

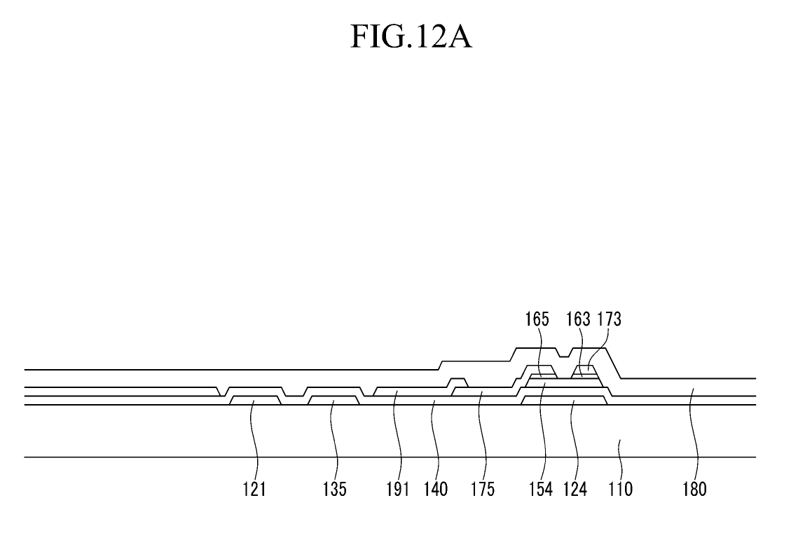

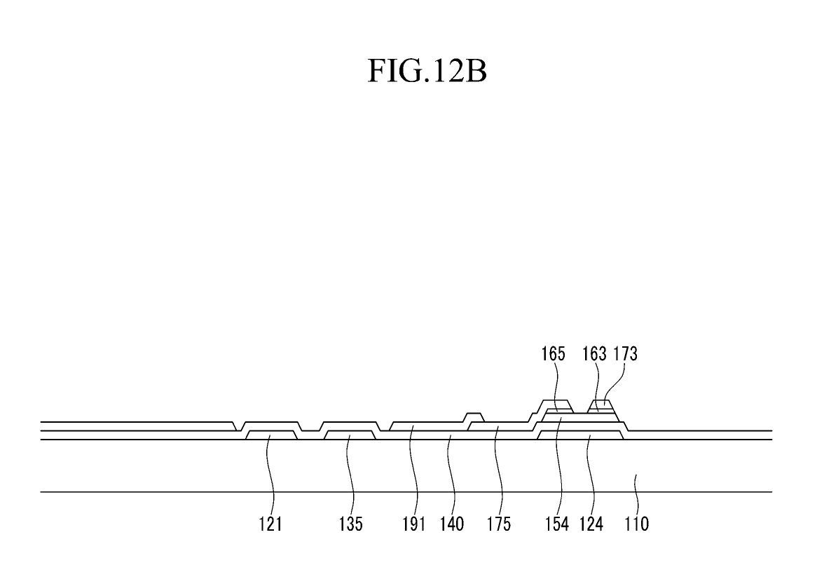

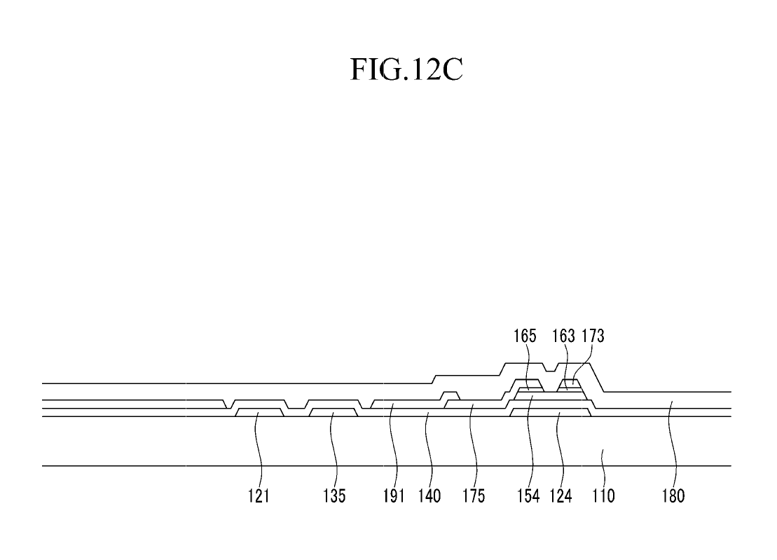

Next, a manufacturing method of a thin film transistor array panel according to another exemplary embodiment of the present invention will be described with reference to FIG. 12A to FIG. 12C. FIG. 12A to FIG. 12C are cross-sectional views sequentially showing a portion of a manufacturing method of a thin film transistor array panel constructed according to another exemplary embodiment of the present invention.

Firstly, as shown in FIG. 12A, a plasma process using a gas including nitrogen and hydrogen is executed on the substrate 110. As above, this prevents performance deterioration of the thin film transistor array panel caused by copper components from the source electrode 173 and drain electrode 175.

Next, as shown in FIG. 12B, a passivation layer 180 is deposited on the substrate 110. Here, the haze phenomenon may be generated in the interface between the pixel electrode 191 and the passivation layer 180.

Next, as shown in FIG. 12C, the deposited passivation layer 180 is removed by etching. The portion containing the haze phenomenon is also removed.

Next, as shown in FIG. 12D, a passivation layer 180 is again deposited. Next, a contact hole (not shown) exposing an end portion of the data line 171 is formed in the passivation layer 180. Also formed are a contact hole 183 exposing the expansion 135 of the reference voltage line 131, and a contact hole (not shown) exposing an end portion of the gate line 121. Each of these latter two contact holes are formed in the passivation layer 180 and the gate insulating layer 140.

As described above, according to the manufacturing method of the thin film transistor array panel according to an exemplary embodiment of the present invention, before forming the passivation layer 180, a plasma process using a gas including nitrogen and hydrogen is executed upon the entire, or substantially entire, surface of the substrate 110, upon which is formed a thin film transistor and a pixel electrode 191 made of a transparent conductor. After depositing the passivation layer 180, the passivation layer 180 is removed by etching such that performance deterioration of the thin film transistor may be prevented a portion of the passivation layer 180 where the haze phenomenon is generated by hydrogen gas is also removed. Next, a passivation layer 180 is again deposited thereon. In this manner, the haze phenomenon known to arise in the transparent electrode due to application of hydrogen gas may be prevented, while also preventing deterioration in the performance characteristic of the thin film transistor.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a thin film transistor array panel, comprising:
forming a gate conductor on a substrate;
forming a gate insulating layer on the gate conductor;
forming a semiconductor, a source electrode, and a drain electrode on the gate insulating layer;
forming a transparent electrode on the gate insulating layer and a portion of the drain electrode;
executing a plasma process during which a mixed gas is directed upon the semiconductor, the source electrode, the drain electrode, the mixed gas including hydrogen gas and nitrogen gas; and
after the executing, forming a passivation layer on the semiconductor, the source electrode, the drain electrode, and the transparent electrode.

2. The method of claim 1, wherein
the mixed gas has a ratio of hydrogen gas to nitrogen gas of about 1:10 to about 1:50.

3. The method of claim 2, wherein
the mixed gas has a ratio of hydrogen gas to nitrogen gas of about 1:10 to about 1:30.

4. The method of claim 3, wherein
the source electrode and the drain electrode include copper.

5. The method of claim 4, wherein
the source electrode and the drain electrode include titanium.

6. The method of claim 4, wherein
the plasma process is executed with a pressure of about 500 mT to about 2500 mT.

7. The method of claim 4, wherein
the plasma process is executed with a power source of 0.1 W/mm² to about 5 W/mm².

8. The method of claim 4, wherein
the plasma process is executed for about 5 seconds to about 50 seconds.

9. The method of claim 1, wherein
the source electrode and the drain electrode include copper.

10. The method of claim 9, wherein
the source electrode and the drain electrode include titanium.

11. The method of claim 9, wherein
the plasma process is executed with a pressure of about 500 mT to about 2500 mT.

12. The method of claim 9, wherein
the plasma process is executed with a power source of 0.1 W/mm² to about 5 W/mm².

13. The method of claim 9, wherein
the plasma process is executed for about 5 seconds to about 50 seconds.

14. The method of claim 1, wherein
the plasma process is executed with a pressure of about 500 mT to about 2500 mT.

15. The method of claim 1, wherein
the plasma process is executed with a power source of 0.1 W/mm² to about 5 W/mm².

16. The method of claim 1, wherein
the plasma process is executed for about 5 seconds to about 50 seconds.

17. A method of manufacturing a thin film transistor array panel, comprising:
forming a gate conductor on a substrate;
forming a gate insulating layer on the gate conductor;
forming a semiconductor, a source electrode, and a drain electrode on the gate insulating layer;
forming a transparent electrode on the gate insulating layer and a portion of the drain electrode;
depositing a first passivation layer on the semiconductor, the source electrode, the drain electrode, and the transparent electrode;
removing the first passivation layer ; and
after the removing, depositing a second passivation layer on the semiconductor, the source electrode, the drain electrode, and the transparent electrode.

18. The method of claim 17, wherein
the source electrode and the drain electrode include copper.

19. The method of claim 18, wherein
the source electrode and the drain electrode include titanium.

20. A thin film transistor array panel comprising:
a gate conductor disposed on a substrate;
a gate insulating layer disposed on the gate conductor;
a semiconductor disposed on the gate insulating layer;
a source electrode and a drain electrode disposed on the semiconductor and the gate insulating layer;
a transparent electrode disposed on the gate insulating layer and a portion of the drain electrode and directly contacting the drain electrode; and
a passivation layer disposed on the source electrode, the drain electrode, and the transparent electrode,
wherein the source electrode, the drain electrode, and the transparent electrode are plasma-processed with a mixed gas including hydrogen gas and nitrogen gas.

21. The thin film transistor array panel of claim 20, wherein
the source electrode and the drain electrode include copper.

22. The thin film transistor array panel of claim 21, wherein
the source electrode and the drain electrode include titanium.
